(19) United States
(12) Patent Application Publication
(10) Pub. No.: US 2014/0266389 A1
(43) Pub. Date: Sep. 18, 2014

(54) Powerline Control Interface

(71) Applicants: Laurence P. Sadwick, Salt Lake City, UT (US); William B. Sackett, Salt Lake City, UT (US)

(72) Inventors: Laurence P. Sadwick, Salt Lake City, UT (US); William B. Sackett, Salt Lake City, UT (US)

(21) Appl. No.: 14/218,905

(22) Filed: Mar. 18, 2014

Related U.S. Application Data
(60) Provisional application No. 61/786,406, filed on Mar. 15, 2013.

(51) Int. Cl. H03K 19/0175

(52) U.S. Cl. CPC H03K 19/0175
USPC 327/333

(57) ABSTRACT

A powerline control interface includes a powerline connection, a level shifter connected to the powerline connection, the level shifter having a zero crossing detector signal output, a capacitor connected to the powerline connection, an inductor connected to the powerline connection, and a receive signal inductively coupled to the inductor.

### BACKGROUND

Electricity is generated and distributed in alternating current (AC) form, wherein the voltage varies sinusoidally between a positive and a negative value. However, many electrical devices require a direct current (DC) supply of electricity having a constant voltage level, or at least a supply that remains positive even if the level is allowed to vary to some extent. For example, most integrated circuits and light emitting diodes (LEDs) and similar devices such as organic light emitting diodes (OLEDs) require electricity to flow in only one direction. LEDs and OLEDs are being increasingly considered for use as light sources in residential, commercial and municipal applications. However, in general, unlike incandescent light sources, LEDs and OLEDs cannot be powered directly from an AC power supply unless, for example, the LEDs are configured in some back to back formation. Electrical current flows through an individual LED easily in only one direction, and if a negative voltage which exceeds the reverse breakdown voltage of the LED is applied, the LED can be damaged or destroyed. Furthermore, the standard, nominal residential voltage level is typically something like 120 VAC or 240 VAC in many parts of the world, both of which are higher than may be desired for a high efficiency LED light. Some conversion of the available power may therefore be necessary or highly desired with loads such as an LED light or other light sources or electrical appliances.

In one type of commonly used power supply for loads such as an LED, an incoming AC voltage is connected to the load only during certain portions of the sinusoidal waveform. For example, a fraction of each half cycle of the waveform may be used by connecting the incoming AC voltage to the load each time the incoming voltage rises to a predetermined level or reaches a predetermined phase and by disconnecting the incoming AC voltage from the load each time the incoming voltage again falls to zero. In this manner, a positive but reduced voltage may be provided to the load. This type of conversion scheme is often controlled so that a constant current is provided to the load even if the incoming AC voltage varies. However, if this type of power supply with current control is used in an LED light fixture or lamp, a conventional dimmer is often ineffective. For many LED power supplies, the power supply will attempt to maintain the constant current through the LED despite a drop in the incoming voltage by increasing the on-time during each cycle of the incoming AC wave.

Dimmer circuits are generally used to regulate the illumination level output from a light by controlling the current, voltage or power available to the light through any of a number of mechanisms or regulation schemes. Dimmer circuits may also be used with other types of loads to control the work performed by the load. Dimmer circuits are typically designed to operate with a specific input voltage. If they are used with a different input voltage, current may rise above safe levels and damage loads such as LEDs. The behavior of the dimmer circuit may also be altered, with the dimming range being compressed or expanded. In addition, dimming using conventional AC dimmers including Triac-based dimmers can often be problematic including for dimming of LEDs, fluorescent lamps (FLs) including cold cathode fluorescent lamps (CCFLs), compact fluorescent lamps (CFLs), energy efficient lighting, etc. Also Triac dimmers in general have poor power factors when dimming, that is phase angle dimming results in a reduced power factor. In addition to controlling the power to light source(s), household, residential and industrial appliance(s) and equipment, entertainment components and systems, heating, ventilation, air conditioning (HVAC) equipment, etc. using Triacs or similar type of dimming, control of the power using commands sent across the power lines (i.e., powerline control) can also accomplish power management as well as one or two-way communications without the issues associated with Triac, Triac-based, and other forward and reverse dimmers including flicker and poor power factor during dimming.

### SUMMARY

A powerline communications interface that can be used for powerline communications via AC lines that is suitable for use with virtually any electronic device, system, unit including, but not limited to, AC or DC power supplies, lighting drivers, ballasts, appliances, equipment, heating, ventilation and air conditioning (HVAC), home entertainment, freezers, refrigerators, dish washers, microwave ovens, toasters, stoves and ovens, furnaces, heaters, etc. is disclosed which can send and/or receive commands that allow variable control and monitoring of electrical devices, systems, components, units, etc. that are plugged in/connected to AC power. The present invention is suitable for use at any AC voltage including both 50 and 60 Hz and from below 80 VAC, at or around 100 to 120 VAC, at or around 200 to 240 VAC, at or around 277 VAC at or around 347 VAC, at or around 480 VAC and higher and any voltage or voltages in between less than 80 VAC to greater than 480 VAC. Such features of the present invention can be selected for example manually or automatically or programmed. The present invention is general purpose and can be used in virtually any application where control or monitoring via the AC lines is used. The present invention can be used in conjunction with other types of communications including wired and wireless communications. In addition, the present invention can also be used to provide an interface for control circuits of virtually all types and forms including but not limited to, microcontrollers, microprocessors, digital signal processors (DSPs), field programmable gate arrays (FPGAs), complex logic devices (CLDs), application specific integrated circuits (ASICs), integrated circuits (ICs), analog to digital converters (ADC) and digital to analog converters (DAC) circuits made of ICs, discrete components, semiconductor electronics and circuits, vacuum tube electronics and circuits, active and passive circuits, analog and/or digital circuits, etc., combinations of these, or subset of these, etc.

### BRIEF DESCRIPTION OF THE DRAWINGS

A further understanding of the various embodiments may be realized by reference to the figures which are described in remaining portions of the specification. In the figures, like reference numerals may be used throughout several drawings to refer to similar components.

FIG. 1 depicts an example circuit that can used to receive powerline communications in accordance with some embodiments.

FIG. 2 depicts an example circuit that can be used in conjunction with the circuit of FIGS. 1, 3, and 4 to provide power to various parts of the complete system and application in accordance with some embodiments.

FIG. 3 depicts an example circuit that can used to transmit powerline communications in accordance with some embodiments.

FIG. 4 depicts an example circuit that can used to receive and transmit powerline communications in accordance with some embodiments.

### DESCRIPTION

Powerline control is used for a variety of residential and industrial applications. These applications are diverse and include large appliances such as refrigerators, washing machines, dryers, etc. to small appliances such as microwave ovens, heaters, computer communications, internet communications, intra- and inter-computer communications, etc. to lighting including the ability to turn on or off or dim lights. Other methods of dimming include the use of phase angle/phase cut dimmers such as Triac dimmers. There are a number of issues with Triacs and other forms of dimming as well as certain types of implementation of powerline control especially as applied to dimming. The present invention addresses this and other limitations and provides circuits for use in powerline applications including for driving various loads including, but not limited to, power supplies, HVAC equipment, appliances, portable heaters, light emitting diodes (LEDs) of all types with some examples being high brightness LEDs, arrays of LEDs and organic LEDs (OLEDs); it is also possible to apply the present invention to dimming fluorescent, incandescent, gas discharge, neon, and/or any combination of lighting, etc. The present invention can be designed to be used in the voltage range of less than 100 VAC including 80 VAC to greater than 277 VAC and up to 480 VAC and higher.

Such dimming systems controlled by the powerline control interface can provide programmable timed or sensor or event-based control, turning on and off current to the load, dimming the load, etc. as programmed. The dimming systems are configured in some embodiments to set and/or store control functions and operations, i.e., scheduling, turn on/off, dim, respond to voice, motion, etc. at certain time(s) each day, multiple times per day, different days of the week, weekends, different dates including day date and month date, etc., in some cases with partial or full randomization of settings. The settings can be stored in any type of memory including volatile, non-volatile, random access memory (RAM), FLASH, EPROM, EEPROM, other semiconductor, magnetic, optical, etc. memories.

Such a dimming to universal control and also on/off control may be hardwired into elements that use the present invention, contained in firmware, be software selectable, be programmed either internally or externally by any method including wireless, wired, optical control, etc., by a switch of any type, either located on the actual light source or elsewhere, by either simple or complex control algorithms, either contained internally within the light source or remote from the light source. The present invention can be implemented in a dimming to constant output mode, a universal dimmer, and numerous other embodiments and implementations that, again, can be manually switched from one mode to another, automatically switched from one mode to another, programmed by a variety of ways including by firmware, hardware, software, wired communications, wireless communications, etc. The present invention can also be used with relays including AC relays, Triacs, transistors as forward or reverse dimmers, silicon controlled rectifiers (SCRs), etc. In some embodiments, the present invention is adapted to operate with existing or other powerline based systems such X10, Insteon, HomePlug, etc

In certain applications, a fast or extremely fast over current, over voltage control signal or signals may be used to limit any parameter or combination of parameters such as voltage, current, power in an instantaneous method and approach to protect, for example, the appliance, light source, etc. from, for example, transients, surges, over-voltages, harmonics, other distortions, etc. that may exist on the line input voltage, from time to time or continuously. Such fast methods of control may or may not preserve the high power factor and may depend on the characteristics and behavior of the input signal; however, in general, preserving the power factor is preferred.

The present invention can also use a reference signal, for example, a reference voltage or current that can be varied with the average or instantaneous input voltage until a maximum level after which the reference voltage or current reaches a maximum level resulting, for example, in a constant output current or constant output voltage that is now independent of, for example, the input voltage and transforms, for example, the light source into a constant output light independent of the input waveforms, levels, etc. above a certain prescribed (but also potentially programmable) input level(s) and associated conditions.

Such a reference signal may consist of, for example, a voltage divider voltage that is directly related to, for example, the peak, instantaneous, average, etc. voltage of the input which can be clamped/clipped/limited to a maximum value, by any means.

As mentioned above, the present invention can be implemented using a number of power supply and driver circuits, including in general, but not limited to, buck, boost, buck-boost, boost-buck, single stage, two stage, fly back, auk, SEPIC, forward converter including but not limited to push pull, single and double forward converters, voltage mode, current mode, voltage fed, current fed, etc., power supplies, both with and without power factor correction, etc. Such dimming to universal control can be accomplished in both isolated and non-isolated designs and implementations, including on the output side and/or the input side of the circuit. The present invention can involve monitoring and controlling one or more signals.

The present invention may involve any combination of time constants, delays, fast and ultrafast response circuits whether digital or analog or both in nature. The present invention may use circuitry to limit or modify, for example, a pulse that drives a transistor to provide either isolated (e.g., transformer) or non-isolated (e.g. inductor) power transfer to an output load or it may, for example, digitally modulate, turn on/off, pulse width modulate (PWM) the pulse to the transistor associated with the transformer, inductor, etc. The present invention includes all types of transformer topologies found in both switching and linear power supplies including, but not limited to, flyback, forward converters and same primary/secondary polarity transformer configurations and topologies.

The present invention can be implemented using constant on time, constant off time, constant frequency/period, constant pulse width, constant duty cycle, or, if preferred, variable on-time, off-time, frequency, etc. can be used to realize and implement the present invention. In addition, dither can be employed to reduce the effects of electromagnetic interference (EMI) with the associated power supplies and electronics.

Referring now to FIG. 1, a schematic diagram of a powerline control (PLC) interface to the AC lines 100 is shown. In this embodiment, the powerline interface is connected to the AC input 100, for example by a 50 or 60 Hz sinusoidal waveform of 120 V or 240 V RMS such as that supplied to residences by municipal electric power companies. It is important to note, however, that the PLC interface is not limited to any particular voltage, current or power input, and that the universal dimmable driver and, for that matter, the universal dimmer may be adapted to operate with any input voltage or with various different input voltages including DC input voltages. In addition to universal dimming, the present invention can be used to control, monitor, log, report, flag, store, analyze, provide analytics, etc. on essentially any type of device, circuit, system, appliance, unit, etc. including, but not limited to, televisions, digital video disc (DVD) players and recorders, stereos, amplifiers, entertainment systems and centers, heaters including electrical heaters and furnaces as well as other types of gas, propane, etc. heaters and furnaces, refrigerators, washing machines, dryers, microwave ovens, electrical and/or gas stoves and/or ovens, dish washer machines and appliances, hot water heater, water purification systems, home alarm systems, home burglar alarms, home monitoring, home security, fire alarm, fire detection and protection, gas detection including, but not limited to, carbon monoxide detectors and sensors, natural gas detectors and sensors, water flow control and monitoring, water leakage detection, air conditioners of any type and form including central air, portable air conditioners, wall mount air conditioners, window mount air conditioners, etc., humidifiers, humidity control and/or monitoring/analytics, etc., temperature control and/or monitoring/analytics, etc., power/current/voltage/energy/etc. control and/or monitoring, etc., off-grid and/or on grid power and energy control and monitoring/analytics, etc. solar and other alternative energy systems control and monitoring/analytics, etc., electric vehicles, hybrid electric vehicles, battery chargers, computers, laptops, servers, other types of electrical chargers including but not limited to wireless power chargers, wireless power transfer, computer-based communications, remote control of electronics including entertainment, appliances, computers, etc., including those discussed herein, etc.

Referring to FIG. 1, fuse 102 is an optional fuse which may or may not be required to meet safety regulations and can be of any appropriate type. Fuse 102 can be shared by other parts of the overall unit including power supplies (i.e., linear and switching, etc.) Capacitor 104 and the inductor in the first side of transformer 106 form an LC circuit with a resonant frequency of f=1/((2π)(L₁C₁)^{1/2}), where L₁ is the inductance of the first side of transformer 106 and C₁ is the capacitance of capacitor 104. The frequency f is used to transmit and receive information via the AC lines 100. In particular, FIG. 1 illustrates the present invention in a receive mode of operation. The second side of inductor/transformer 106 is used, as illustrated in FIG. 1, to isolate and feed the information signals via the Detection/Level Shift signal 110 to other parts of the circuit including, but not limited to, microcontroller(s), microprocessor(s), DSP(s), FPGA(s), ASIC(s), digital and analog circuits, etc. Transformer/inductor 106 can be made of essentially any type of inductor/transformer including toroidal, C, EE, RM, or E cores, etc., or other core types or other types of inductors, transformers, etc. Resistor 112 and level shifter 114 form a zero-crossing detect (ZCD) circuit that can be used for timing and synchronization purposes. The zero-crossing signal ZCD 116 can also be and often is fed to another input of the microcontroller(s), microprocessor(s), DSP(s), FPGA(s), ASIC(s), digital and analog circuits, etc.

Referring now to FIG. 2, a simple AC to DC power/voltage supply is illustrated which can be used to supply power to the illustrative example embodiments depicted in FIGS. 1, 3 and 4. Fuse 122 can be the same (or a different) fuse than shown in FIG. 1. Diode bridge 124 rectifies the AC input voltage from AC input 120. Resistors 132, 126, Zener diode 130, transistor 134 and optional capacitor 136 provide a constant operating voltage VDD 140, for use with the present invention and potentially other parts of the circuit, including the microcontroller(s), etc. FIG. 2 is merely meant to be illustrative of one method to obtain VDD 140 and should not be viewed in any way or form as limiting to the present invention. In general any type of power supply can be used including, but not limited to, linear and switching power supplies. The power supply depicted in FIG. 2 can be put in parallel at the AC lines (e.g., 120, 100) with the present invention.

In general, for most applications involving AC to DC rectification and output, the AC input is connected to an EMI filter and a rectifier to rectify and invert any negative voltage component from the AC input. The output may isolated by transformer which may or may not be center tapped, may or may not have multiple taps, may or may not have one or more biases/secondaries/auxiliary outputs/auxiliary/fan outputs, etc. The transformer can be of essentially any type including toroidal, C or E cores, or other core types other inductor types and, in general, should be designed for low loss however this is not critical in general. The transformer can have a single primary and a single secondary coil or the transformer can have either multiple primaries and/or secondaries or both, including one or more bias and/or auxiliary coils to provide power to various parts of the dimmer power supply driver. In addition, high voltage transformers may also be used with the present invention. Some embodiments may use a transformer in the flyback mode of operation to realize an efficient circuit with, for example, very high power factor approaching unity and with isolation between the AC input and the LED output. Such an embodiment can also readily support internal dimming. For versions and embodiments of the present invention that use inductors, including, but not limited to those shown in FIGS. 1, 3 and 4, one or more tagalong inductors may be used to, among other things, improve efficiency. A non-limiting example of such tagalong inductors is disclosed in U.S. patent application Ser. No. 13/674,072 entitled “Dimmable LED Driver with Multiple Power Sources”, filed Nov. 11, 2012, the entirety of which is incorporated herein by reference for all purposes.

Referring now to FIG. 3, fuse 102 is an optional fuse which may or may not be required to meet safety regulations and can be of any appropriate type. Fuse 102 can be shared by other parts of the overall unit including power supplies (i.e., linear and switching, etc.) Capacitor 104 and the inductor in the first side of transformer 106 form an LC circuit with a resonant frequency of f=1/((2π)(L₁C₁)^{1/2}), where L₁ is the inductance of the first side of transformer 106 and C₁ is the capacitance of capacitor 104. The frequency f is used to transmit and receive information via the AC lines 100. In FIG. 3, a simple transmit circuit is shown with transistor 150 and resistor 152 forming a part of the transmit circuit with typically the other side of resistor 152 being fed by a signal from a microprocessor, etc. The collector of transistor 150 feeds the second side of inductor 106, as illustrated in FIG. 3, to isolate and feed the information signals to the AC lines 100 from other parts of the circuit including, but not limited to, microcontroller(s), microprocessor(s), DSP(s), FPGA(s), ASIC(s), digital and analog circuits, etc. Transformer 106 can be made of essentially any type of inductor/transformer including toroidal, C, EE, RM, or E cores, etc., or other core types and/or other inductor or transformer types. Resistor 112 and level shifter 114 form a zero-crossing detect (ZCD) circuit that can be used for timing and synchronization purposes. The zero-crossing signal ZCD 116 can also be and often is fed to another input of the microcontroller(s), microprocessor(s), DSP(s), FPGA(s), ASIC(s), digital and analog circuits, etc. The level shifter 114 can take many forms and is some embodiments and implementations may be optional. The level shifter 114 can, for example but not limited to, be an optoisolator, optocoupler, including alternating current (AC) also referred to as bidirectional optoisolators/optocouplers/etc. in which there is an optocoupler in both directions (i.e., two optocouplers in the opposite directions such that it can accept an AC input) and other such devices and level shifters. Any type of optical level shifter including optocouplers and optoisolators made with BJTs, diodes, FETs, MOSFETs, other semiconductor devices, etc. as photosensors for the optoisolator, optocoupler. Some embodiments of the present invention may use diode and/or diode bridges to rectify the AC input to DC and, for example, use single optocouplers/optoisolators, etc. In other embodiments no optoisolator/optocouplers are used and other components such as resistors, diodes including, in some embodiments, Zener diodes, etc. or capacitors and other components that may include resistors, diodes, etc. In general for many applications some form of zero detecting/zero sensing is used in embodiments of the present invention. Still other embodiments and implementations of the present invention no zero sensing/zero detecting ZCD is needed or required. Although a BJT is shown for transistor 150 in FIG. 3, in general any other type of transistor or vacuum tube could be used including, but not limited to MOSFETs, JFETs, GaNFETs, SiCFETs, HBTs, IGBTs, MODFETs, etc.

Referring now to FIG. 4, fuse 102 is an optional fuse which may or may not be required to meet safety regulations and can be of any appropriate type. Fuse 102 can be shared by other parts of the overall unit including power supplies (i.e., linear and switching, etc.) Capacitor C1 and inductor L2 form an LC circuit with a resonant frequency of f=1/((2π) (L₂C₁)^{1/2}), where L₁ is the inductance of the first side of transformer 106 and C₁ is the capacitance of capacitor 104. The frequency f is used to transmit and receive information via the AC lines 100. An additional winding has been added to the second side of transformer 106 to facilitate separate receive and transmit capabilities. The second side of transformer 106 is used, as illustrated in FIG. 4, to isolate and feed the information signals via the Detection/Level Shift signal 110 and the transmit to and from, respectively, other parts of the circuit including, but not limited to, microcontroller(s), microprocessor(s), DSP(s), FPGA(s), ASIC(s), digital and analog circuits, etc. Transformer 106 L2 can be made of essentially any type of inductor/transformer including toroidal, C, EE, RM, or E cores, etc., or other core types and essentially any inductor type and form. The present invention can also be capacitive coupled. Such an additional winding is optional and not required with some embodiments of the present invention using the same winding and/or same inductor to both transmit and receive. Resistor 112 and level shifter 114 form a zero-crossing detect (ZCD) circuit that can be used for timing and synchronization purposes. The zero-crossing signal ZCD 116 can also be and often is fed to another input of the microcontroller(s), microprocessor(s), DSP(s), FPGA(s), ASIC(s), digital and analog circuits, etc. In general, any number of winding of any type and form may be used with the present invention. In terms of ZCD, the discussion above also applies. Note in some embodiments of the present invention, the AC voltage may be less than 80 VAC—as an example, but not limiting in any way or form, is a low voltage (i.e., 12 VAC or 24 VAC) input/system/etc. In still other application and associated embodiments a DC input voltage is used with the present invention. For example low voltage track lighting that typically operates around 12 to 24 volts AC or DC depending on the particulars of the system, etc. Embodiments and implementations of the present invention for use with, for example, track lighting, including but not limited to track lighting of any voltage (or, for example, current), can include a transmitter which is either attached to the AC mains or DC primary power or is attached to the track lighting voltage (again, low voltage or high voltage track lighting), such that commands can be sent from the powerline control/controller to the devices, circuits, lights, lamps including but not limited to LEDs, OLEDs, fluorescent lamps in general of all kinds and types, etc. Such a powerline control/controller, in some embodiments and implementations of the present invention, can be placed directly on the track and control the light and lamp sources and other types of appliances, fans, other elements and items discussed herein, etc. The controller can accept, use, communicate, respond, be controlled by, monitor, data log, provide analytics, etc. by any means, ways, approaches, methods, techniques, etc. discussed herein, including all wireless including RF and/or optically including but not limited to fiberoptic and infrared, wired, and others. For example the present invention can be implemented to be wirelessly via, for example, but not limited to Bluetooth, ZigBee, Z-wave, WiFi, ISM, radio, etc. receive signals and control information to control, dim, log, preset, set, etc. a track light/lamps or track lights/lamps including but not limited to, individually, collectively, subsets of, etc., including, but not limited to, a white light of any color temperature including but not limited to bright white, daylight white, cool white, warm white, etc. from less than 2000 kelvin to greater than 10,000 Kelvin, etc. and color changing lights of single, two, more than two, multiple colors, etc., including but not limited to red green blue (RGB), red yellow blue (RYB), white red green blue (WRGB or RGBW), white red yellow blue (WRYB or RYBW), white red yellow blue amber (WRYBA or RYBAW), white red green blue amber (WRGBA or RGBAW), etc. and, in general, any number of colors, arrays, strings, combinations of LEDs and/or OLEDs in parallel and/or series, etc. including M arrays, strings, etc. of LEDs, OLEDs and/or other light sources, lamps, emitters, strings, etc. where M is greater or equal to one and N colors of such lights, lamps, fixtures, bulbs, luminaires, etc. where N is greater than 1, etc. including but not limited to anything discussed herein.

With reference to an isolated embodiment of the present invention, a power supply with a transformer will be described. With an AC input, typically most active electronics using at least one switching power supply are connected through a fuse and an electromagnetic interference (EMI) filter. As in previously described embodiments, the fuse may be any device suitable to protect the present invention from overvoltage or overcurrent conditions. The AC input is rectified typically in a rectifier bridge. Certain embodiments of the present invention can use, for example, gate transformers or high speed optocouplers/optoisolators. Other embodiments of the present invention can use slower or slow optocouplers/optoisolators or no optocouplers/optoisolators at all. Embodiments of the present invention can use some information to control the current during dimming in any manner or form deemed desirable including digitally transforming the dimming information into a linear, sub-linear, super-linear, quadratic, power-law, square-root, logarithmic, exponential, etc. function and behavior of the load current (or voltage or, for example, power) including the current through (or the voltage across) LEDs or OLEDs and the current through (or the voltage across) CCFLs, FLs, CFLs, HIDs, etc. such as to actively control for example either or both the current or the voltage to the load.

(Notably, some reference numbers herein refer to figures in U.S. patent application Ser. No. 13/773,407 which has been incorporated by reference.)

Any suitable mechanism to connect electrical signals to the present invention can be used. For example, a microcontroller or suitable alternatives may monitor the input voltage 16 and turn on a transistor such as a NPN bipolar transistor or MOSFET to connect to a dimming modifier such as a second slope resistor. Such alternatives may include microprocessors, digital signal processors (DSPs), state machines, digital logic, analog and digital logic, application specific integrated circuits (ASICs), field programmable gate arrays (FPGAs), configurable logic devices (CLDs), etc. Any suitable method including hardware, firmware, software, algorithms, etc. may be used. Note that MOSFETs, junction FETs, any most any other type of transistor could in general be used in place of the BJT.

As mentioned previously, other relationships and functions besides linearly proportional can be used. In addition, should isolation be necessary, an optocoupler, for example, can also be configured and used in a digital on/off fashion rather than as in an analog fashion as illustrated in the embodiments and implementations shown and may also be connected to other parts of the present invention. Again, nothing in this document should be construed or viewed as limiting in any way or form for the present universal dimmer power driver invention discussed here.

Again, the dimming response can be, for example but not limited to, linear, sub-linear, super-linear, square, square-root, power-law, logarithmic, exponential, piece-wise, essentially any function, etc.

The microcontroller or other such control unit such as a microprocessor, ASIC, DSP, ASIC with built-in DSP, ASICs with built in microcontrollers and/or microprocessors, etc., FPGA, etc. may be configured to produce an output signal The present invention can, for example, provide a digital representation and effectively digitize the phase angle information into on or off, true or false, high or low, one or zero, or, for example, a 0 or 5 V signal, a 0 or 10 V signal, etc. using a phase processor which in some example embodiments is a microcontroller that takes in and effectively analyzes the phase information from a dimmer detector and processes that information to a usable result.

Examples of such results could be a digital signal such as a pulse width modulated signal with, for example, a frequency in the range of a few to several hundred Hertz (or higher) that feeds to and modulates the output current (or voltage) from full set current (or voltage) to fully off with a PWM relationship related to the Triac or other phase dimmer phase information. The PWM output result can also be effectively turned into an averaged analog signal by inserting a capacitor in between the resulting output of the phase processor and the circuit/components that set and control the output current (or voltage). With the present invention, the driver or power supply can be designed and implemented to put out a set current (or voltage) output regardless of the input AC voltage that effectively allows a set output current over whatever specified input voltage including a universal voltage range such as, for examples, 100 to 240 VAC, 80 to 305 VAC and higher. The phase angle can be digitized into any number of bits including, for example, 8 bits (i.e., 256 levels), 10 bits (i.e., 512 levels), 12 bits (i.e., 1024 levels), and higher, etc. The digitization of the phase angle dimmer signal/information can be accomplished by a number of methods including, but not limited to, using a detector that measures the on and off time of the Triac or other phase angle dimmer. In some embodiments, the detector comprises a Zener diode in series with one of more resistors that may also be in series or parallel with other resistors such as to produce a saturated or maximum signal (for example 10 V) that can be further scaled (including up and down in voltage range) and fed into, for example but not limited to, a microcontroller or microcontrollers, microprocessor(s), FPGA(s), DSP(s), digital state machines, application specific integrated circuit(s) (ICs), other ICs, system on a chip (SOC), other analog and digital circuits, etc. that produces an output signal or signals that can be fed to the current (or voltage) control circuitry, electronics, and systems, etc. A combination of analog and digital or analog or digital circuits including those incorporated into ASICs, ICs, etc. may be used. As mentioned previously, the current (or voltage) can be controlled, commanded, set in either a digital fashion (e.g., PWM duty cycle on/off modulated) or analog (e.g., reduced or increased in amplitude/value/level as the dimmer dimming level is reduced or increased, respectively).

In various embodiments, 0-10 dimming can be readily and easily implemented with the present invention by providing a 0 to 10 V dimming signal (or a scaled version—e.g., 0 to 3 V using a simple voltage divider) in place of or in conjunction with the phase processor signal that is applied to either or both the reference that sets the current (or voltage) level or the pulse width generator input. For example, this can be accomplished by providing a 0-10 V dimming signal to a phase processor for use in controlling the output 612 of the phase processor or by providing the 0-10 V dimming signal to the reference current generator against which the load current measurement is compared or by providing the 0 to 10 V signal (or an appropriately scaled version) to the input of the PWM pulse width generator. Some embodiments may be dual dimming, supporting the use of a 0-10 V dimming signal in addition to a Triac-based or other phase-cut or phase angle dimmer. In addition, the resulting dimming, including current or voltage dimming, can be either PWM (digital) or analog dimming or both or selectable either manually, automatically, or by other methods and ways including software, remote control of any type including wired, wireless, PLC, etc.

A microcontroller(s), microprocessor(s), DSP(s), FPGAs, CLD(s), ASICs, ICs, etc., a combinations of these embedded or not into an IC, etc. to drive, for example a MOSSFET (or other type of transistor or switch including, but not limited to a BJT, JFET, SiCFET, GaNFET, etc.) so as to be able to provide either (or both) a forward or reverse phase angle/phase cut dimmer that can be designed and implemented to operate over any voltage range including, but not limited to, 100 to 120 VAC, 100 to 240 VAC, 100 to 277 VAC, 100 to 305 VAC, 200 to 240 VAC, 347 VAC, 480 VAC, 100 to 480 VAC, etc. Other zero-detect circuits as well as zero-detect/zero-crossing circuits that do not require either an opto-coupler or a separate bridge can be used with the embodiments depicted in FIGS. 1, 2 and 3. Again, the zero-crossing detector is meant to be an illustrative example and not to be limiting in any way or form.

The present invention can be applied to all sorts and types of general and specialized appliances, heating ventilation and air conditioning (HVAC), thermostats, lighting including but not limited to cold cathode fluorescent lamps (CCFLs), fluorescent lamps (FLs), compact fluorescent lamps (CFLs), light emitting diodes (LEDs), organic LEDs (OLEDs), high intensity discharge (HID), etc. in addition to other driver, ballast and general usage power supply applications.

The present invention may provide thermal control or other types of control to, for example, a dimming LED driver. For example, the circuits shown in the figures or variations thereof may also be adapted to provide overvoltage or overcurrent protection, short circuit protection for, for example, a dimming LED driver, or to override and cut the phase and power to the dimming LED driver(s) based on any arbitrary external signal(s) and/or stimulus. The present invention can also include circuit breakers including solid state circuit breakers and other devices, circuits, systems, etc. that limit or trip in the event of an overload condition/situation. The present invention can also include, for example, other interfaces and analog or digital controls including but not limited to wired (i.e., 0 to 10 V, RS 232, RS485, IEEE standards, SPI, I2C, other serial and parallel standards and interfaces, etc.), wireless, including powerline including powerline control (PLC) protocols, algorithms, digital representations, etc. and can be implemented in any part of the circuit for the present invention. Additional remote interfaces include, but are not limited to, 0 to 10 V, 0 to 2 V, 0 to 1 V, 0 to 3 V, etc., RS 232, RS485, DMX, WiFi, Bluetooth, ZigBee, Z-wave, IEEE 802, two wire, three wire, SPI, I2C, PLC, and others discussed in this document, etc. The present invention can also support color LED and/or OLED lighting including, but not limited to, AC lighting and fluorescent lamp replacements including single and multi-color including RGB, White plus red-green-blue (RGB) LEDs or OLEDs or other lighting sources, RGB plus one or more colors, red yellow blue (RYB), other variants, etc. Color-changing/tuning can include more than one color including RGB, WRGB, WRGBA where A stands for amber, etc. 5 color, 6 color, N color, etc. Color-changing/tuning can include, but is not limited to, white color-tuning including the color temperature tuning/adjustments/settings/etc., color correction temperature (CCT), color rendering index (CRI), etc. Color rendering, color monitoring, color feedback and control can be implemented using wired or wireless circuits, systems, interfaces, etc. that can be interactive using for example, but not limited to, smart phones, tablets, computers, laptops, servers, remote controls, etc. Color temperature monitoring, feedback, and adjustment can be performed in such embodiments of the present invention. The ability to change to different colors when using light sources capable of supporting such (i.e., LEDs and OLEDs including but not limited to red, green, blue, amber, white LEDs and/or any other possible combination of LEDs and colors). Embodiments of the present invention has the ability to store color choices, selections, etc. and retrieve, restore, display, update, etc. these color choices and selections when using non-fluorescent light sources that can support color changing. Embodiments of the present invention also have the ability to change between various color choices, selections, and associated inputs to do as well as the ability to modulate the color choices and selections.

In some embodiments, dimming or/other control can be performed using methods/techniques/approaches/algorithms/etc. that implement one or more of the following: motion detection, recognizing motion or proximity to a detector or sensor and setting a dimming level or control response/level in response to the detected motion or proximity, or with audio detection, for example detecting sounds or verbal commands to set the dimming level in response to detected sounds, volumes, or by interpreting the sounds, including voice recognition or, for example, by gesturing including hand or arm gesturing, etc. sonar, light, mechanical, vibration, detection and sensing, etc. Some embodiments may be dual or multiple dimming and/or control, supporting the use of multiple sources, methods, algorithms, interfaces, sensors, detectors, protocols, etc. to control and/or monitor including data logging, data mining and analytics. Some embodiments of the present invention may be multiple dimming or control (i.e., accept dimming information, input(s), control from two or more sources). The present invention can be used with a buck, a buck-boost, a boost-buck and/or a boost, flyback, or forward-converter design etc., topology, implementation, etc.

Other embodiments can use comparators, other op amp configurations and circuits, including but not limited to error amplifiers, summing amplifiers, log amplifiers, integrating amplifiers, averaging amplifiers, differentiators and differentiating amplifiers, etc. and/or other digital and analog circuits, microcontrollers, microprocessors, complex logic devices, field programmable gate arrays, etc.

The present invention includes implementations that contain various other control circuits including, but not limited to, linear, square, square-root, power-law, sine, cosine, other trigonometric functions, logarithmic, exponential, cubic, cube root, hyperbolic, etc. in addition to error, difference, summing, integrating, differentiators, etc. type of op amps. In addition, logic, including digital and Boolean logic such as AND, NOT (inverter), OR, Exclusive OR gates, etc., complex logic devices (CLDs), field programmable gate arrays (FPGAs), microcontrollers, microprocessors, application specific integrated circuits (ASICs), etc. can also be used either alone or in combinations including analog and digital combinations for the present invention. The present invention can be incorporated into an integrated circuit, be part of an integrated circuit, etc.

The present invention may use and be configured to work with power supplies, drivers, etc. that operate, for example, in continuous conduction mode (CCM), critical conduction mode (CRM), discontinuous conduction mode (DCM), resonant conduction modes, etc., with any type of circuit topology including but not limited to buck, boost, buck-boost, boost-buck, auk, SEPIC, flyback, forward-converters, etc. For the respective configurations, examples of which are mentioned above, constant on time, constant off time, constant frequency/period, variable frequency, variable on time, variable off time, etc., as examples, can be used with the present invention. The present invention works with both isolated and non-isolated designs including, but not limited to, buck, boost-buck, buck-boost, boost, flyback and forward-converters. The present invention itself may also be non-isolated or isolated, for example using a tag-along inductor or transformer winding or other isolating techniques, including, but not limited to, transformers including signal, gate, isolation, etc. transformers, optoisolators, optocouplers, etc.

The present invention includes other implementations that may contain various other control circuits including, but not limited to, linear, square, square-root, power-law, sine, cosine, other trigonometric functions, logarithmic, exponential, cubic, cube root, hyperbolic, etc. in addition to error, difference, summing, integrating, differentiators, etc. type of op amps. In addition, logic, including digital and Boolean logic such as AND, NOT (inverter), OR, Exclusive OR gates, etc., complex logic devices (CLDs), field programmable gate arrays (FPGAs), microcontrollers, microprocessors, application specific integrated circuits (ASICs), etc. can also be used either alone or in combinations including analog and digital combinations for the present invention. The present invention can be incorporated into an integrated circuit, be an integrated circuit, etc.

The present invention can also incorporate at an appropriate location or locations one or more thermistors (i.e., either of a negative temperature coefficient [NTC] or a positive temperature coefficient [PTC]) to provide temperature-based load current limiting.

When the temperature rises at the selected monitoring point(s), the phase dimming of the present invention can be designed and implemented to drop, for example, by a factor of, for example, two. The output power, no matter where the circuit was originally in the dimming cycle, will also drop/decrease by some factor. Values other than a factor of two (i.e., 50%) can also be used and are easily implemented in the present invention by, for example, changing components of the example circuits described here for the present invention. As an example, a resistor change would allow and result in a different phase/power decrease than a factor of two. The present invention can be made to have a rather instant more digital-like decrease in output power or a more gradual analog-like decrease, including, for example, a linear decrease in output phase or power once, for example, the temperature or other stimulus/signal(s) trigger/activate this thermal or other signal control.

In other embodiments, other temperature sensors may be used or connected to the circuit in other locations. The present invention also supports external dimming by, for example, an external analog and/or digital signal input. One or more of the embodiments discussed above may be used in practice either combined or separately including having and supporting both 0 to 10 V and digital dimming. The present invention can also have very high power factor. The present invention can also be used to support dimming, power reduction, power cycling, brown-out, etc.

The transistors, switches and other devices, etc. may include any suitable type of transistor or other device, such as a bipolar transistor, including bipolar junction transistors (BJTs) and insulated gate bipolar transistors (IGBTs), or a field effect transistor (FET) including n and/or p channel FETs such as junction FETs (JFETs), metal oxide semiconductor FETs (MOSFETs), metal insulator FETs (MISFETs), metal emitter semiconductor FETs (MESFETs) of any type and material including but not limited to silicon, gallium arsenide, indium phosphide, gallium nitride, silicon carbide, silicon germanium, diamond, graphene, and other binary, ternary and higher order compounds of these and other materials. In addition, complementary metal oxide semiconductor n and p channel MOSFET (CMOS), heterojunction FET (HFET) and heterojunction bipolar transistors (HBT), bipolar and CMOS (BiCMOS), BCD, modulation doped FETs, (MODFETs), etc, and can be made of any suitable material including ones made of silicon, gallium arsenide, gallium nitride, silicon carbide, etc. which, for example, has a suitably high voltage rating.

The variable pulse generator may use any suitable control scheme, such as duty cycle control, frequency control, pulse width control, pulse width modulation, etc. Any type of topology including, but not limited to, constant on time, constant off time, constant, frequency, variable frequency, variable duration, discontinuous, continuous, critical conduction modes of operation, CUK, SEPIC, boost-buck, buck-boost, buck, boost, etc. may be used with the present invention. The use of the term variable pulse generator is not intended to be limiting in any way or form but merely to attempt to describe part of the function performed by the present invention, namely to provide a signal that switches power (i.e., current and voltage) to a load such as the LED discussed in the present invention. The variable pulse generator can be made, designed, built, manufactured, implemented, etc. in various ways including those involving digital logic, digital, circuits, state machines, microelectronics, microcontrollers, microprocessors, digital signal processors (DSPs), field programmable gate arrays (FPGAs), complex logic devices (CLDs), microcontrollers, microprocessors, analog circuits, discrete components, band gap references and generators, timer circuits and chips, ramp generators, half bridges, full bridges, level shifters, difference amplifiers, error amplifiers, logic circuits, comparators, operational amplifiers, flip-flops, counters, AND, NOR, NAND, OR, exclusive OR gates, etc. or various combinations of these and other types of circuits.

The above is merely meant to provide illustrative examples and should not be construed or taken as limiting in any or form for the present invention.

What is claimed is:

1. An apparatus for communicating via powerline, comprising:
a powerline connection;
a level shifter connected to the powerline connection, the level shifter comprising a zero crossing detector signal output;
a capacitor connected to the powerline connection;
an inductor connected to the powerline connection; and
a receive signal inductively coupled to the inductor.
